(19) United States
(12) Patent Application Publication
(10) Pub. No.: US 2026/0221983 A1
(43) Pub. Date: Jul. 30, 2026

(54) COMPARATOR, ANALOG TO DIGITAL CONVERTER, AND OFFSET CANCELLATION METHOD THEREOF

(71) Applicant: REALTEK SEMICONDUCTOR CORPORATION, HSICHU (TW)

(72) Inventor: WEI-CIAN HONG, Hsinchu (TW)

(21) Appl. No.: 19/180,211

(22) Filed: Apr. 16, 2025

(30) Foreign Application Priority Data
May 7, 2024 (TW) 113116904

(51) Int. Cl. H03M 1/10

(52) U.S. Cl. CPC H03M 1/1023

(57) ABSTRACT

A comparator includes a comparator circuit, an offset calculation circuit, a hybrid offset voltage generation circuit, and an offset cancellation circuit. The comparator circuit is configured to generate a decision signal according to an input signal. The offset calculation circuit is configured to calculate an offset of the comparator circuit according to the decision signal to generate a plurality of control signals. The hybrid offset voltage generation circuit is configured to select a first reference voltage and a second reference voltage from a plurality of reference voltages according to the control signals and utilize the first reference voltage and the second reference voltage to perform a charge transfer operation to generate a plurality of calibration voltages. The offset cancellation circuit is configured to cancel the offset according to the plurality of calibration voltages.

### BACKGROUND OF THE INVENTION

### 1. Field of the Invention

The present disclosure relates to a comparator, especially a comparator with an offset cancellation mechanism, an analog-to-digital converter that employs that comparator, and an offset cancellation method thereof.

### 2. Description of Related Art

Analog-to-digital converters often utilize comparators to perform quantization operations. To achieve better performance, the offset of the comparator is required to be canceled. In the existing approaches, through offset cancellation mechanisms, the offset is processed to be typically converged to a smaller value. To further reduce the offset to an even smaller value or even to zero, it is usually required to increase the number of circuits employed in the offset cancellation mechanism to generate a finer calibration voltage. As a result, the overall circuit complexity and circuit area are increased. Additionally, increasing the number of circuit components may introduce more noise, resulting in a circuit performance degradation.

### SUMMARY OF THE INVENTION

In some aspects, an object of the present application is, but not limited to, provide a comparator having an offset cancellation mechanism, an analog-to-digital converter that employs that comparator, and an offset cancellation method thereof so as to make an improvement to the prior art.

In some aspects of the present disclosure, a comparator includes a comparator circuit, an offset calculation circuit, a hybrid offset voltage generation circuit, and an offset cancellation circuit. The comparator circuit is configured to generate a decision signal according to an input signal. The offset calculation circuit is configured to calculate an offset of the comparator circuit according to the decision signal to generate a plurality of control signals. The hybrid offset voltage generation circuit is configured to select a first reference voltage and a second reference voltage from a plurality of reference voltages according to the control signals and utilize the first reference voltage and the second reference voltage to perform a charge transfer operation to generate a plurality of calibration voltages. The offset cancellation circuit is configured to cancel the offset according to the plurality of calibration voltages.

In some aspects of the present disclosure, an analog-to-digital converter includes a plurality of comparator circuits, an offset calculation circuit, a hybrid offset voltage generation circuit, and a plurality of offset cancellation circuits. The plurality of comparator circuits are configured to generate a plurality of decision signals according to an input signal. The offset calculation circuit is configured to calculate an offset of the plurality of comparator circuits according to the plurality of decision signals to generate a plurality sets of control signals. The hybrid offset voltage generation circuit is configured to select a first reference voltage and a second reference voltage from a plurality of reference voltages according to the plurality sets of control signals and utilize the first reference voltage and the second reference voltage to perform a charge transfer operation to generate a plurality sets of calibration voltages. The plurality of offset cancellation circuits are configured to cancel the offset according to the plurality sets of calibration voltages.

In some aspects of the present disclosure, an offset cancellation method includes the following operations: generating, by a comparator circuit, a decision signal according to an input signal; calculating an offset of the comparator circuit according to the decision signal to generate a plurality of control signals; selecting a first reference voltage and a second reference voltage from a plurality of reference voltages according to the plurality of control signals, in order to utilize the first reference voltage and the second reference voltage to perform a charge transfer operation to generate a plurality of calibration voltages; and cancelling the offset of the comparator circuit according to the plurality of calibration voltages.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a schematic diagram of a comparator according to some embodiments of the present disclosure.

FIG. 2 illustrates a schematic diagram of the comparator circuit and the offset cancellation circuit in FIG. 1 according to some embodiments of the present disclosure.

FIG. 3A illustrates a schematic diagram of the hybrid offset voltage generation circuit in FIG. 1 according to some embodiments of the present disclosure.

FIG. 3B illustrates a schematic diagram of the hybrid offset voltage generation circuit in FIG. 1 according to some embodiments of the present disclosure.

FIG. 4A illustrates a schematic diagram of the switching capacitor circuit in FIG. 3A according to some embodiments of the present disclosure.

FIG. 4B illustrates a schematic diagram of the switching capacitor circuit in FIG. 3B according to some embodiments of the present disclosure.

FIG. 5A illustrates a schematic diagram of the switching capacitor circuit in FIG. 3A according to some embodiments of the present disclosure.

FIG. 5B illustrates a schematic diagram of the switching capacitor circuit in FIG. 3B according to some embodiments of the present disclosure.

FIG. 6A illustrates a schematic diagram of an analog-to-digital converter according to some embodiments of the present disclosure.

FIG. 6B illustrates a schematic diagram of the hybrid offset voltage generation circuit in FIG. 6A according to some embodiments of the present disclosure.

FIG. 7 illustrates a flowchart of an offset cancellation method according to some embodiments of the present disclosure.

### DETAILED DESCRIPTION OF THE PREFERRED EMBODIMNETS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuit” may indicate an object, which is formed with one or more transistors and/or one or more active/passive elements based on a specific arrangement, for processing signals.

As used herein, the term "and/or" includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, like elements in various figures are designated with the same reference number.

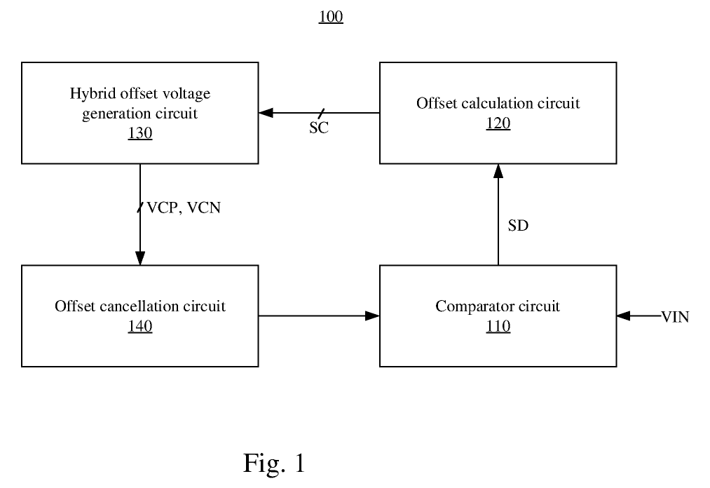

FIG. 1 illustrates a schematic diagram of a comparator 100 according to some embodiments of the present disclosure. The comparator 100 includes a comparator circuit 110, an offset calculation circuit 120, a hybrid offset voltage generation circuit 130, and an offset cancellation circuit 140. The comparator circuit 110 may be, but is not limited to, a dynamic comparator circuit with positive feedback, which may generate a decision signal SD according to an input signal VIN. The offset calculation circuit 120 may calculate an offset of the comparator circuit 110 according to the decision signal SD to generate control signals SC. In some embodiments, the offset calculation circuit 120 may be implemented with a digital signal processing circuit that performs a statistical operation. The offset calculation circuit 120 may perform the statistical operation (which may be, for example but not limited to, an averaging operation) according to the decision signal SD to estimate the offset of the comparator circuit 110 and correspondingly generate the control signals SC.

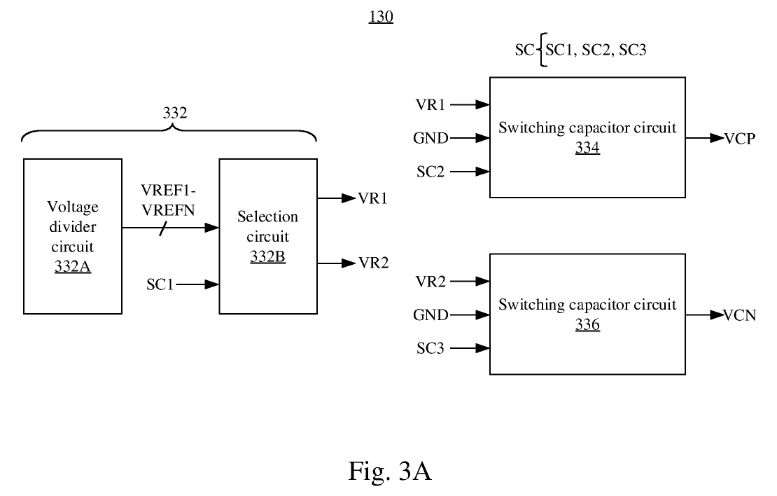

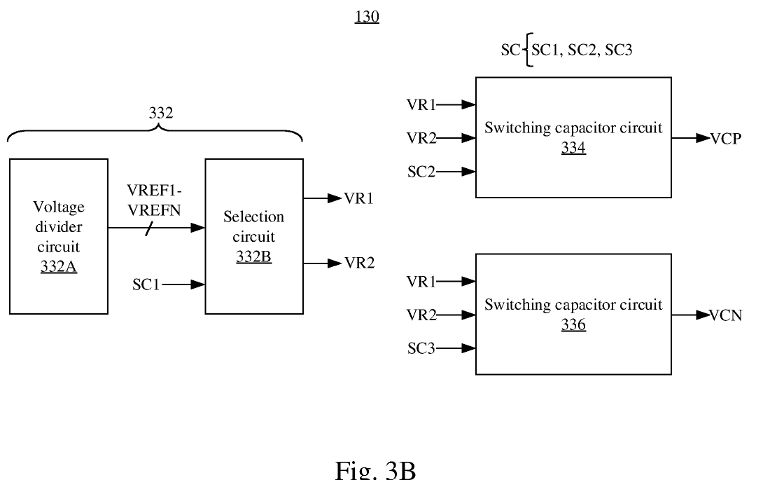

The hybrid offset voltage generation circuit 130 may select a first reference voltage and a second reference voltage from reference voltages (e.g., reference voltages VREF1-VREFN in FIG. 3A) according to the control signals SC, in order to utilize the first reference voltage and second reference voltage to perform a charge transfer operation to generate calibration voltages VCP and VCN. Details regarding the configuration of the hybrid offset voltage generation circuit 130 will be described later with reference to other figures. The offset cancellation circuit 140 may cancel the offset of the comparator circuit 110 according to the calibration voltages VCP and VCN. As a result, the negative effects of the offset on the comparator circuit 110 (e.g., including unnecessary noise) can be reduced, thereby improving the overall performance of the comparator 100.

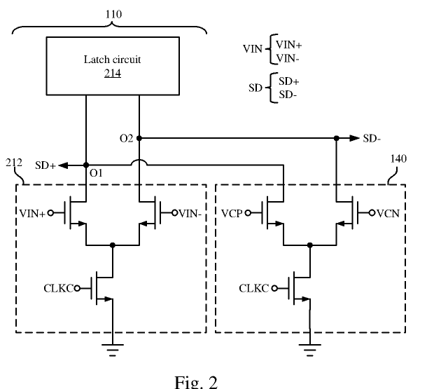

FIG. 2 illustrates a schematic diagram of the comparator circuit 110 and the offset cancellation circuit 140 in FIG. 1 according to some embodiments of the present disclosure. The comparator circuit 110 includes an input pair circuit 212 and a latch circuit 214. The input pair circuit 212 and the latch circuit 214 are coupled to a node O1 and a node O2. The latch circuit 214 may perform the aforementioned positive feedback mechanism. The input pair circuit 212 may compare an input signal VIN+ with an input signal VIN- when a clock signal CLKC is at a predetermined level (which may be a high level in this example) to output a decision signal SD+ and a decision signal SD- via the node O1 and the node O2, respectively. In some embodiments, the input pair circuit 212 and the latch circuit 214 are coupled at the node O1 and node O2, such that the decision signals SD+ and the decision signals SD- may be output via the latch circuit 214. In some embodiments, the input signal VIN in FIG. 1 may be a set of differential signals (e.g., the input signals VIN+ and the input signal VIN- in FIG. 2). Correspondingly, in some embodiments, the decision signal SD in FIG. 1 may be a set of differential signals (e.g., the decision signal SD+ and the decision signal SD- in FIG. 2). In this example, the configuration of the offset cancellation circuit 140 corresponds to the configuration of the input pair circuit 212, which may drain and/or inject current from/to the node O1 and the node O2 according to the calibration voltages VCP and VCN when the clock signal CLKC is at the predetermined level, thereby cancelling the offset of the comparator circuit 110.

The above configuration of the offset cancellation circuit 140 are given for illustrative purposes, and the present disclosure is not limited thereto. Various circuits able to cancel the offset of the comparator circuit 110 according to the calibration voltages VCP and VCN are within the contemplated scope of the present disclosure.

FIG. 3A illustrates a schematic diagram of the hybrid offset voltage generation circuit 130 in FIG. 1 according to some embodiments of the present disclosure. The hybrid offset voltage generation circuit 130 may include a digital-to-analog converter circuit 332 and switching capacitor circuits 334 and 336. The digital-to-analog converter circuit 332 may generate reference voltages VREF1-VREFN and select a reference voltage VR1 and a reference voltage VR2 from the reference voltages VREF1-VREFN according to a first signal SC1 of the control signals SC. In some embodiments, the digital-to-analog converter circuit 332 may include a voltage divider circuit 332A and a selection circuit 332B. The voltage divider circuit 332A may divide the system voltage to generate the reference voltages VREF1-VREFN. In some embodiments, the voltage divider circuit 332A may be implemented with resistors coupled in series. The selection circuit 332B may select the reference voltage VR1 and the reference voltage VR2 from the reference voltages VREF1-VREFN according to the first signal SC1. In some embodiments, the selection circuit 332B may be a multiplexer implemented with switches. For example, when the offset calculation circuit 120 determines that the average value of the decision signal SD is too large, the offset calculation circuit 120 may output the corresponding control signals SC to select the reference voltage VR1 with a higher level and the reference voltage VR2 with a lower level. Alternatively, when the offset calculation circuit 120 determines that the average value of the decision signal SD is too small, the offset calculation circuit 120 may output the corresponding control signals SC to select the reference voltage VR1 with a lower level and the reference voltage VR2 with a higher level. In some embodiments, the difference between the calibration voltages VCP and VCN will converge to a stable voltage value and fluctuate around this stable voltage value. In some embodiments, the offset calculation circuit 120 may output the control signals SC according to an upper limit of the fluctuation range of this difference to select the corresponding reference voltages VR1 and VR2. In some embodiments, the upper limit of the fluctuation range of this difference may be determined according to system requirements.

The switching capacitor circuits 334 and 336 may perform the charge transfer operation according to the reference voltage VR1, the reference voltage VR2, and a second signal SC2 and a third signal SC3 in the control signals SC to generate the calibration voltages VCP and VCN. In this example, the switching capacitor circuit 334 may perform the charge transfer operation according to the reference voltage VR1, the ground voltage GND, and the second signal SC2 to generate the calibration voltage VCP. Correspondingly, the switching capacitor circuit 336 may perform the charge transfer operation according to the reference voltage VR2, the ground voltage GND, and the third signal SC3 to generate the calibration voltage VCN.

FIG. 3B illustrates a schematic diagram of the hybrid offset voltage generation circuit 130 in FIG. 1 according to some embodiments of the present disclosure. Different from FIG. 3A, in this example, the switching capacitor circuit 334 may perform the charge transfer operation according to the reference voltage VR1, the reference voltage VR2, and the second signal SC2 to generate the calibration voltage VCP. The switching capacitor circuit 336 may perform the charge transfer operation according to the reference voltage VR1, the reference voltage VR2, and the third signal SC3 to generate the calibration voltage VCN. In other words, in different embodiments, the switching capacitor circuit 334 may perform the charge transfer operation according to the reference voltage VR1, the second signal SC2, and one of the ground voltage GND and the reference voltage VR2, to generate the calibration voltage VCP. Similarly, in different embodiments, the switching capacitor circuit 336 may perform the charge transfer operation according to the reference voltage VR2, and the third signal SC3, and one of the ground voltage GND and the reference voltage VR1, to generate the calibration voltage VCN.

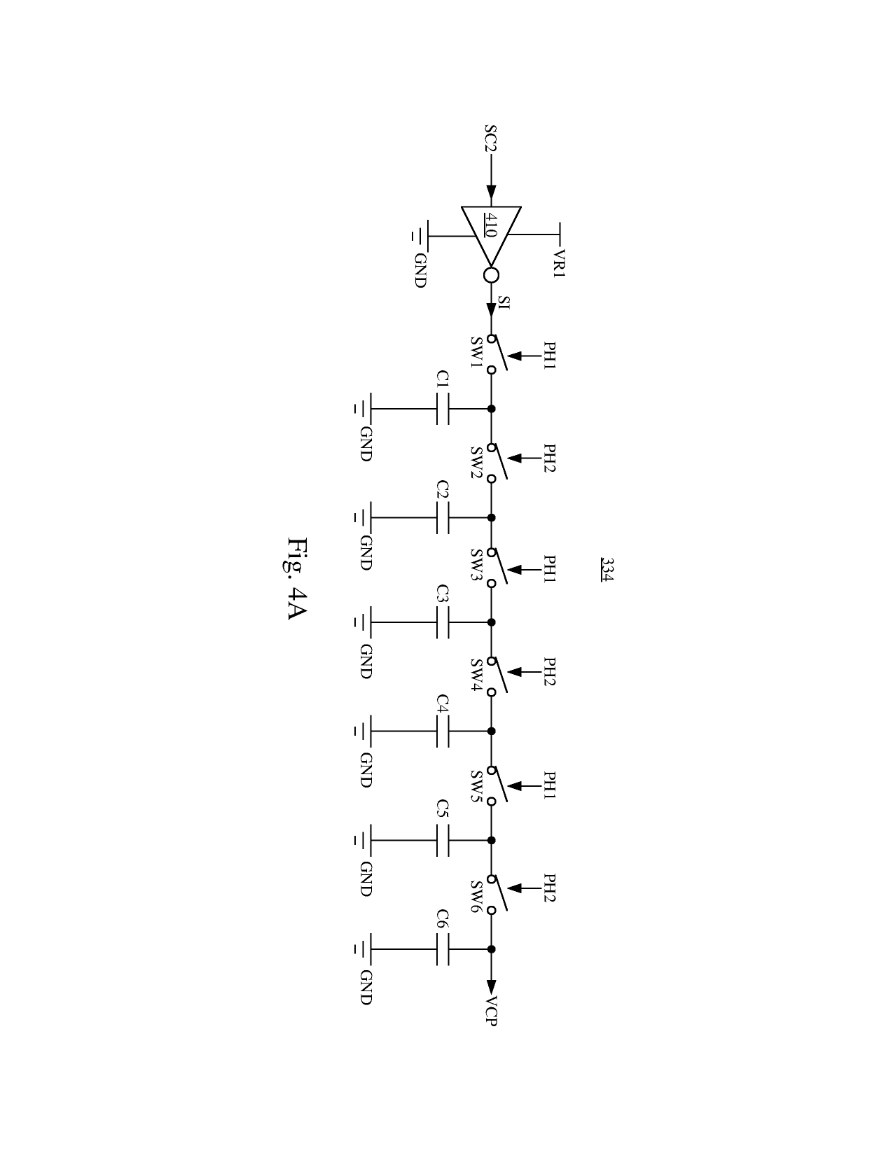

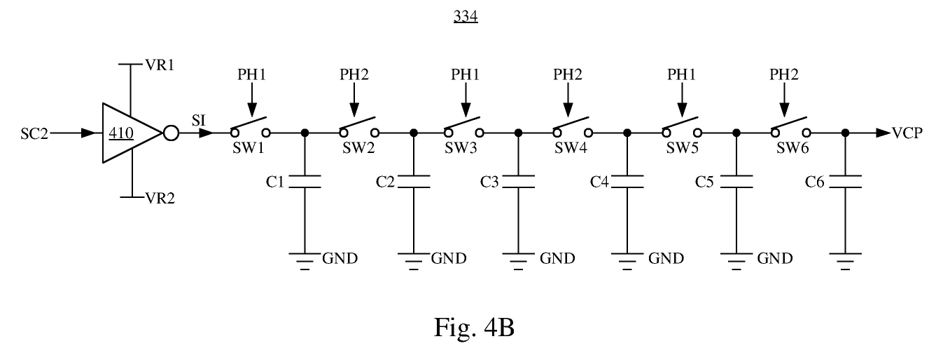

FIG. 4A illustrates a schematic diagram of the switching capacitor circuit 334 in FIG. 3A according to some embodiments of the present disclosure. In this example, the switching capacitor circuit 334 may include an inverter 410, capacitors C1-C6, and switches SW1-SW6. The inverter 410 is powered by the reference voltage VR1 and the ground voltage GND and generates an inverted signal SI according to the second signal SC2. The switches SW1-SW6 are respectively turned on according to clock signals PH1 and PH2, in order to transmit the inverted signal SI to the capacitors C1-C6, such that the capacitors C1-C6 perform the charge transfer operation in response to the inverted signal SI to generate the calibration voltage VCP.

In greater detail, a first terminal of the switch SW1 is coupled to the inverter 410 to receive the inverted signal SI, a second terminal of the switch SW1 is coupled to the capacitor C1, and a control terminal of the switch SW1 receives the clock signal PH1. A first terminal of the switch SW2 is coupled to the capacitor C1 and the second terminal of the switch SW1, a second terminal of the switch SW2 is coupled to the capacitor C2, and a control terminal of the switch SW2 receives the clock signal PH2. With this analogy, the corresponding configurations of the remaining switches SW3 -SW6 and capacitors C3-C6 can be understood. With the aforementioned configuration, when the switch SW1 is turned on, the capacitor C1 may be charged or discharged by the inverted signal SI. Subsequently, when the switch SW2 is turned on, the capacitor C2 may transfer a portion of its charge(s) from the capacitor C1. Similarly, when the subsequent switches SW3-SW6 are turned on, the capacitors C3 -C6 may perform the above charge transfer operation correspondingly, to generate the calibration voltage VCP via the capacitor C6 (corresponding to the amount of charge(s) stored in the capacitor C6).

It is understood that, if the reference voltage VR1 is higher, the amount of charge(s) transferred through the capacitors C1-C6 will increase, resulting in a greater variation in the calibration voltage VCP. Alternatively, if the reference voltage VR1 is lower, the amount of charge(s) transferred through the capacitors C1-C6 will decrease, leading to a smaller variation in the calibration voltage VCP. On the other hand, if the number of switches and capacitors employed in the switching capacitor circuit 334 increases, the number of charge transfer operation being performed will also increase, causing the amount of charge(s) stored in the last capacitor to decrease, thereby reducing the variation in the calibration voltage VCP. In other words, With the aforementioned configuration, the digital-to-analog converter circuit 332 is able to generate reference voltages VR1 with different levels, and the variation in the calibration voltage VCP is able to be reduced by adjusting the number of switches and capacitors in the switching capacitor circuit 334, thereby minimizing the fluctuation range of the aforementioned difference. As a result, it is able to cancel the offset in the comparator circuit 110 more precisely.

In some related approaches, the calibration voltage is generated by only utilizing switching capacitor circuits or resistor-based digital-to-analog converters. In such cases, achieving more precise offset elimination requires a larger number of capacitors and switches (or resistors) to sufficiently reduce the variation in the calibration voltage. Compared to these related approaches, in some embodiments of the present disclosure, the hybrid offset voltage generation circuit 130 employs a voltage division mechanism to generate lower reference voltages, such that the switching capacitor circuit 334 (and/or the switching capacitor circuit 336) is able to reduce the variation in the calibration voltage VCP without using an excessive number of capacitors and switches. As a result, it is able to enable more precise offset cancellation while saving circuit area.

FIG. 4B illustrates a schematic diagram of the switching capacitor circuit 334 in FIG. 3B according to some embodiments of the present disclosure. Different from FIG. 4A, in this example, the inverter 410 is powered by the reference voltages VR1 and VR2 and generates the inverted signal SI according to the second signal SC2. In some embodiments, the reference voltage VR1 is higher than the reference voltage VR2. With the aforementioned configuration, both of the upper limit (i.e., the reference voltage VR1) and the lower limit (i.e., the reference voltage VR2) of the level of the inverted signal SI may be further adjusted. As a result, it is able to generate a finer calibration voltage VCP.

In some embodiments, the configuration of the switching capacitor circuit 336 is the same as that of the switching capacitor circuit 334. For example, according to the configuration in FIG. 4A, the inverter of the switching capacitor circuit 336 (corresponding to the inverter 410) is powered by the reference voltage VR2 and the ground voltage GND and generates the inverted signal SI according to the third signal SC3. Alternatively, according to the configuration in FIG. 4B, the inverter of the switching capacitor circuit 336 (corresponding to the inverter 410) is powered by the reference voltages VR1 and VR2 and generates the inverted signal SI according to the third signal SC3. The remaining configurations can be understood with reference to FIGS. 4A and 4B and the aforementioned descriptions, and thus the repetitious descriptions are not further given.

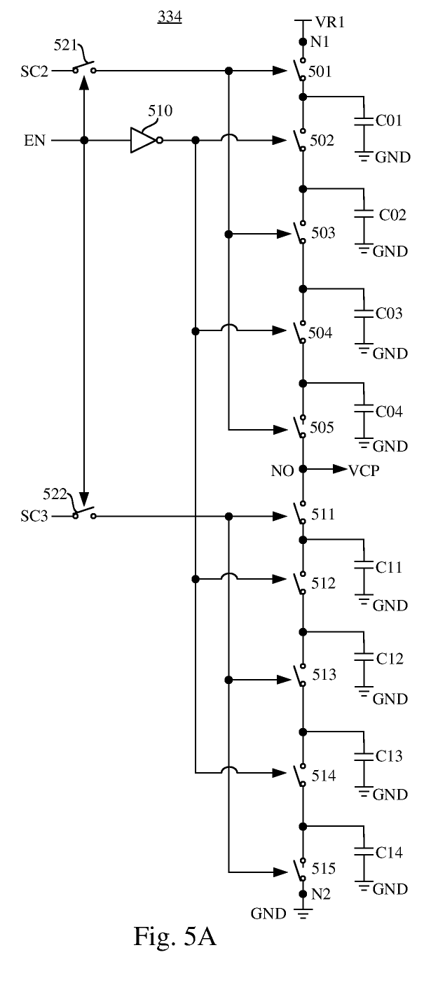

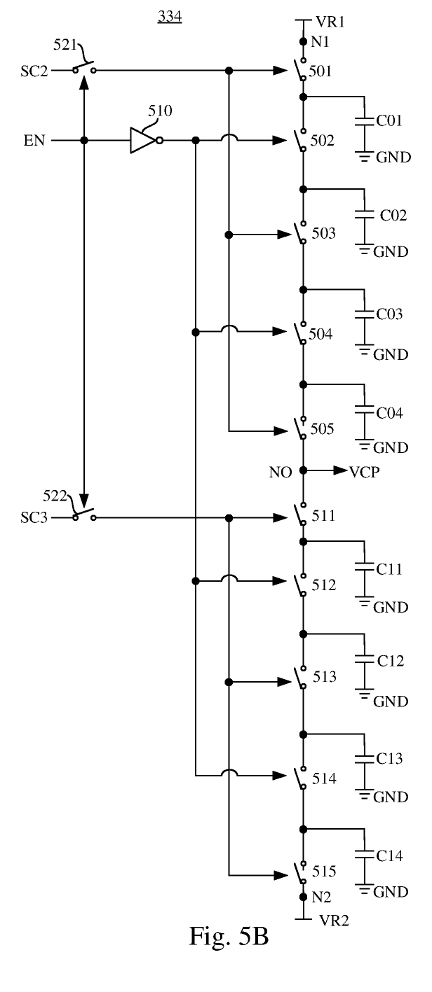

FIG. 5A illustrates a schematic diagram of the switching capacitor circuit 334 in FIG. 3A according to some embodiments of the present disclosure. In this example, the switching capacitor circuit 334 may include switches 501-505, capacitors C01-C04, switches 511-515, capacitors C11-C14, an inverter 510, and switches 521 and 522. The switches 501-505 are coupled in series and between a node N1 and an output node NO and are selectively turned on according to the second signal SC2 and an enable signal EN, in which the node N1 is configured to receive the reference voltage VR1, and the output node NO is configured to output the calibration voltage VCP. The switches 521 and 522 are turned on according to the enable signal EN to selectively transmit the second signal SC2 and the third signal SC3 to the corresponding switches in the switches 501-505 and the switches 511-515. In greater detail, a first terminal of the switch 501 is coupled to the node N1, a second terminal of the switch 501 is coupled to a first terminal of the switch 502 and the capacitor C01, and a control terminal of the switch 501 receives the second signal SC2 via the switch 521. A second terminal of the switch 502 is coupled to a first terminal of the switch 503 and the capacitor C02, and a control terminal of the switch 502 receives the enable signal EN via the inverter 510 (i.e., the switch 502 receives the inverted enable signal EN). With this analogy, the corresponding configurations of the remaining switches 503-505 and capacitors C03-C04 can be understood.

Similarly, the switches 511-515 are coupled in series and between the output node NO and a node N2 and are selectively turned on according to the third signal SC3 and the enable signal EN, in which the node N2 is configured to receive the ground voltage GND. In greater detail, a first terminal of the switch 511 is coupled to the output node NO, a second terminal of the switch 511 is coupled to a first terminal of the switch 512 and the capacitor C11, and a control terminal of the switch 511 receives the third signal SC3 via the switch 522. A second terminal of the switch 512 is coupled to a first terminal of the switch 513 and the capacitor C12, and a control terminal of the switch 512 receives the enable signal EN via the inverter 510. With this analogy, the corresponding configurations of the remaining switches 513-515 and capacitors C13-C14 can be understood.

With the aforementioned configuration, the capacitors C01-C04 and C11-C14 may perform the charge transfer operation via the switches 501-505 and 511-515 to output the calibration voltage VCP through the output node NO. For example, the capacitors C01-C04 may be charged and/or discharged in response to the switching of the switches 501-505, and the capacitors C11-C14 may be charged and/or discharged in response to the switching of the switches 511-515. After the charges in the capacitors C01-C04 and C11-C14 are redistributed via the switches 501-505 and 511-515, the switching capacitor circuit 334 may output the corresponding calibration voltage VCP through the output node NO. Similarly, if the reference voltage VR1 is higher, the amount of transferable charge(s) will increase, resulting in a greater variation in the calibration voltage VCP. Alternatively, if the reference voltage VR1 is lower, the amount of transferable charge(s) will decrease, leading to a smaller variation in the calibration voltage VCP. If the number of switches and capacitors employed in the switching capacitor circuit 334 increases, the number of charge transfer operation will also increase, thereby reducing the variation in the calibration voltage VCP. In other words, the aforementioned configuration may effectively reduce the variation in the calibration voltage VCP, in order to cancel the offset in the comparator circuit 110 more precisely.

FIG. 5B illustrates a schematic diagram of the switching capacitor circuit 334 in FIG. 3B according to some embodiments of the present disclosure. Different from FIG. 5A, in this example, the node N2 receives the reference voltage VR2 instead of the ground voltage GND. In other words, in different embodiments, the node N2 may be configured to receive either the ground voltage GND or the reference voltage VR2. With the aforementioned configuration, a finer calibration voltages VCP may be generated.

In some embodiments, the configuration of the switching capacitor circuit 336 is the same as that of the switching capacitor circuit 334. For example, according to the configuration in FIG. 5A, the node N1 of the switching capacitor circuit 336 receives the reference voltage VR1. Alternatively, according to the configuration in FIG. 5B, the node N1 and the node N2 of the switching capacitor circuit 336 respectively receive the reference voltage VR1 and the reference voltage VR2. The remaining configurations can be understood with reference to FIGS. 5A and 5B and the aforementioned descriptions, and thus the repetitious descriptions are not further given.

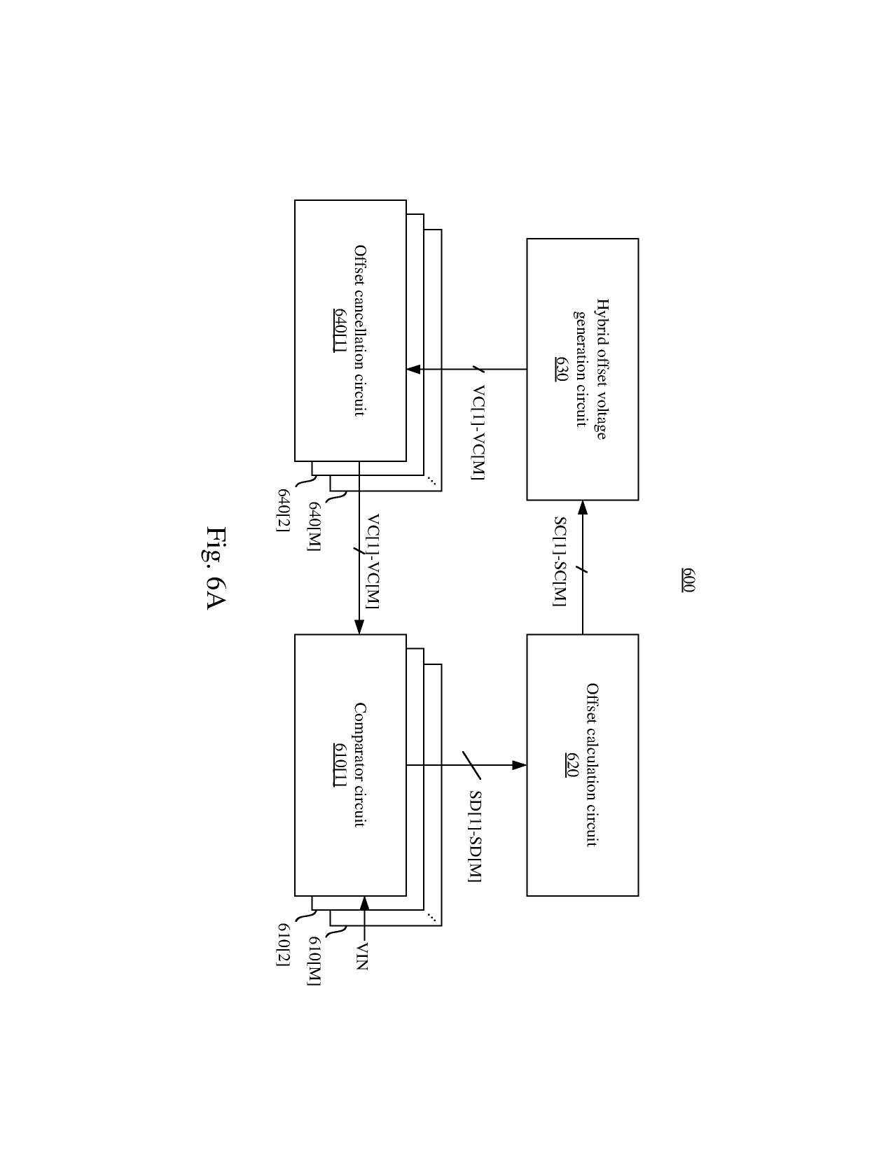

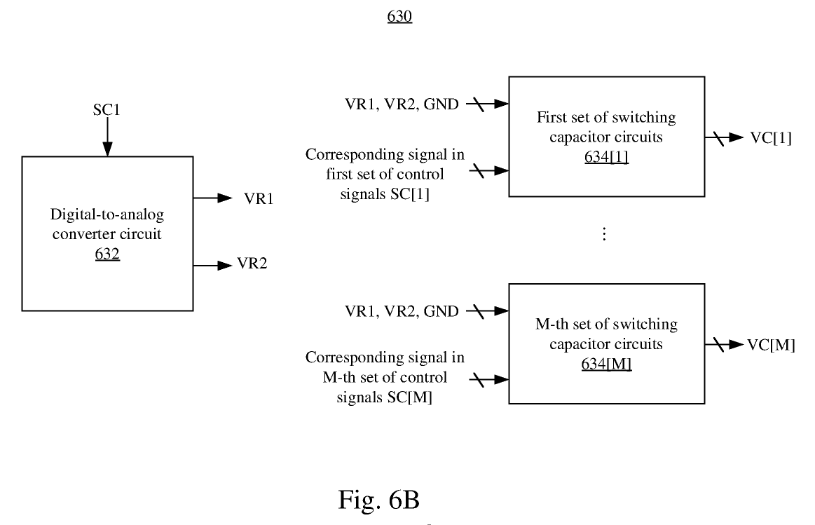

FIG. 6A illustrates a schematic diagram of an analog-to-digital converter 600 according to some embodiments of the present disclosure. In some embodiments, the analog-to-digital converter 600 may be a time-interleaved analog-to-digital converter or an analog-to-digital converter that employs multiple comparators.

The analog-to-digital converter 600 may include comparator circuits 610[1]-610[M], an offset calculation circuit 620, a hybrid offset voltage generation circuit 630, and offset cancellation circuits 640[1]-640[M]. The comparator circuits 610[1]-610[M] may perform an analog-to-digital conversion according to the input signal VIN to generate decision signals SD[1]-SD[M]. The offset calculation circuit 620 may perform the aforementioned statistical operation according to the decision signals SD[1]-SD[M] to determine the offset of the comparator circuits 610[1]-610[M], in order to generate sets of control signals SC[1]-SC[M].

In some embodiments, the decision signals SD[1]-SD[M] may be combined into a digital code with N bits, where both M and N are positive integers greater than 1. Under this condition, the offset calculation circuit 620 may also perform the statistical operation according to this digital code to determine and generate the sets of control signals SC[1]-SC[M]. The hybrid offset voltage generation circuit 630 may select a first reference voltage and a second reference voltage (e.g., the aforementioned reference voltages VR1 and VR2) from reference voltages according to the sets of control signals SC[1]-SC[M] and utilize the first reference voltage and the second reference voltage to perform the charge transfer operation to generate sets of calibration voltages VC[1]-VC[M]. The offset cancellation circuits 640[1]-640[M] may cancel the offsets in the comparator circuits 610[1]-610[M] according to the sets of calibration voltages VC[1]-VC[M]. For example, the offset cancellation circuit 640[1] may calibrate the comparator circuit 610[1] according to a corresponding set of calibration voltages VC[1], and the offset cancellation circuit 640[2] may calibrate the comparator circuit 610[2] according to a corresponding set of calibration voltages VC[2]. With this analogy, the correspondence between the aforementioned circuits and the sets of calibration voltages can be understood. In this example, each set of calibration voltages VC[1]-VC[M] may include the aforementioned calibration voltages VCP and VCN. The related configurations of the aforementioned circuits can be understood with reference to the aforementioned descriptions of the above embodiments, and thus the repetitious descriptions will not be further given.

FIG. 6B illustrates a schematic diagram of the hybrid offset voltage generation circuit 630 in FIG. 6A according to some embodiments of the present disclosure. The hybrid offset voltage generation circuit 630 includes a digital-to-analog converter circuit 632 and sets of switching capacitor circuits 634[1]-634[M]. The configuration of the digital-to-analog converter circuit 632 can be understood with reference to the configuration of the digital-to-analog converter circuit 332 in FIG. 3A. Similarly, each set of the switching capacitor circuits 634[1]-634[M] may include the switching capacitor circuits 334 and 336 shown in FIGS. 3A, 3B, 4A or 4B. The detailed configurations can be understood with reference to the above embodiments, and thus repetitious descriptions are not further given. The sets of switching capacitor circuits 634[1]-634[M] may perform the charge transfer operation according to a corresponding signal in the sets of control signal SC[1]-SC[M] (e.g., including the aforementioned second signal SC2 and third signal SC3) to generate the sets of calibration voltages VC[1]-VC[M]. In greater detail, in some embodiments, the first set of control signals SC[1] may include three signals, such as the first signal SC1, the second signal SC2, and the third signal SC3 in FIGS. 3A or 3B, where the first signal SC1 may be provided to the digital-to-analog converter circuit 632. On the other hand, each of the remaining sets of control signals SC[2]-SC[M] may include two signals, such as the second signal SC2 and the third signal SC3 in FIGS. 3A or 3B, which may be utilized to control a corresponding set of circuits in the switching capacitor circuits 634[2]-634[M]. The aforementioned configuration of the sets of control signals SC[1]-SC[M] is given for illustrative purposes, and the present disclosure is not limited thereto.

From FIG. 6B, it is understood that, the set number of sets of switching capacitor circuits 634[1]-634[M] (e.g., the value M) is the same as the number of comparator circuits 610[1]-610[M], and all sets of switching capacitor circuits 634[1]-634[M] receive the reference voltages VR1 and VR2 generated from the same digital-to-analog converter circuit 632. In other words, the switching capacitor circuits 634[1]-634[M] may share the digital-to-analog converter circuit 632. As a result, the number of circuit components is further reduced, in order to decrease the circuit area and cost required for the analog-to-digital converter 600.

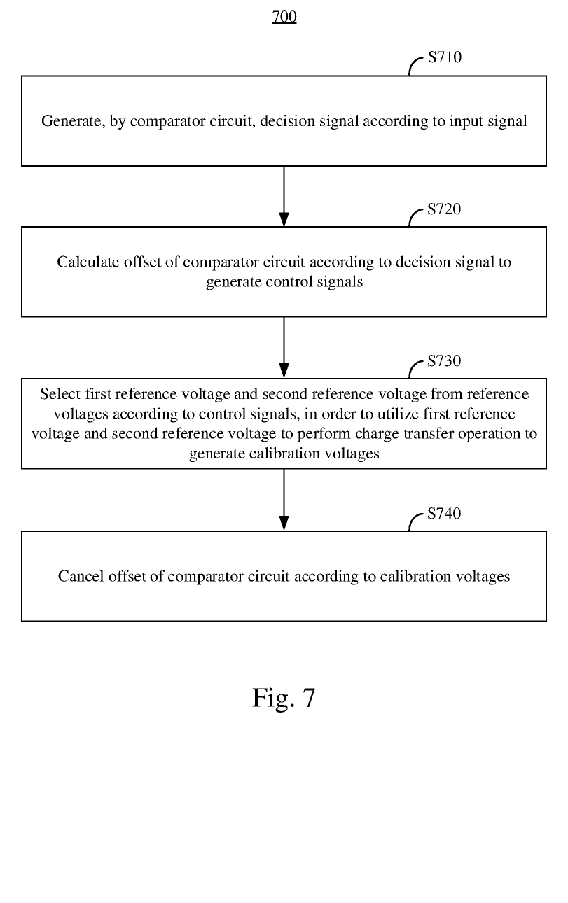

FIG. 7 illustrates a flowchart of an offset cancellation method 700 according to some embodiments of the present disclosure. In operation S710, a decision signal is generated by a comparator circuit according to an input signal. In operation S720, an offset of the comparator circuit is calculated according to the decision signal to generate control signals. In operation S730, a first reference voltage and a second reference voltage are selected from reference voltages according to the control signals to utilize the first reference voltage and the second reference voltage to perform a charge transfer operation to generate calibration voltages. In operation S740, the offset of the comparator circuit is canceled according to the calibration voltages.

The above operations can be understood with reference to the above embodiments, and thus the repetitious descriptions are not further given. Operations of the offset cancellation method 700 include exemplary operations, but those operations are not necessarily performed in the order described above. Operations of the offset cancellation method 700 may be added, replaced, changed order, and/or eliminated, or the operations of the offset cancellation method 700 can be performed simultaneously or partially simultaneously as appropriate, in accordance with the spirit and scope of various embodiments of the present disclosure.

As described above, the comparator, analog-to-digital converter, and offset cancellation method provided in some embodiments of the present disclosure may generate fine calibration voltages through various configurations, thereby more precisely cancelling the offset of the comparator. On the other hand, with the aforementioned configurations, the required number of circuits may be reduced, thereby decreasing circuit area and cost.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically comprise transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely the preferred embodiments of the present disclosure, without any intention to limit the scope of the present disclosure thereto. Various equivalent changes, alterations, or modifications based on the claims of the present disclosure are all consequently viewed as being embraced by the scope of the present disclosure.

What is claimed is:

1. A comparator, comprising:
a comparator circuit configured to generate a decision signal according to an input signal;
an offset calculation circuit configured to calculate an offset of the comparator circuit according to the decision signal to generate a plurality of control signals;
a hybrid offset voltage generation circuit configured to select a first reference voltage and a second reference voltage from a plurality of reference voltages according to the control signals and utilize the first reference voltage and the second reference voltage to perform a charge transfer operation to generate a plurality of calibration voltages; and
an offset cancellation circuit configured to cancel the offset according to the plurality of calibration voltages.

2. The comparator of claim 1, wherein the hybrid offset voltage generation circuit comprises:
a digital-to-analog converter circuit configured to generate the plurality of reference voltages and select the first reference voltage and the second reference voltage from the plurality of reference voltages according to a first signal of the plurality of control signals; and
a plurality of switching capacitor circuits configured to perform the charge transfer operation according to a second signal and a third signal of the plurality of control signals, the first reference voltage, and the second reference voltage, to generate the plurality of calibration voltages.

3. The comparator of claim 2, wherein the plurality of switching capacitor circuits comprises:
a first switching capacitor circuit configured to perform the charge transfer operation according to the first reference voltage, the second signal, and one of a ground voltage and the second reference voltage to generate a first calibration voltage of the plurality of calibration voltages; and
a second switching capacitor circuit configured to perform the charge transfer operation according to the second reference voltage, the third signal, and one of the ground voltage and the first reference voltage to generate a second calibration voltage of the plurality of calibration voltages.

4. The comparator of claim 3, wherein the first switching capacitor circuit comprises:
an inverter configured to be powered by the first reference voltage and the one of the ground voltage and the second reference voltage and generate an inverted signal according to the second signal;
a plurality of capacitors; and
a plurality of switches configured to be turned on according to a plurality of clock signals to transmit the inverted signal to the plurality of capacitors,
wherein the plurality of capacitors are configured to perform the charge transfer operation in response to the inverted signal to generate the first calibration voltage.

5. The comparator of claim 3, wherein the first switching capacitor circuit comprises:
a plurality of first switches, coupled in series and between a first node and an output node, and configured to be selectively turned on according to the second signal and an enable signal, wherein the first node is configured to receive the first reference voltage;
a plurality of first capacitors coupled to the plurality of first switches;
a plurality of second switches, coupled in series and between the output node and a second node, and configured to be selectively turned on according to the third signal and the enable signal, wherein the second node is configured to receive the one of the ground voltage and the second reference voltage;
a plurality of second capacitors coupled to the plurality of second switches, wherein the plurality of first capacitors and the plurality of second capacitors are configured to perform the charge transfer operation through the plurality of first switches and the plurality of second switches to output the first calibration voltage via the output node; and
a plurality of third switches configured to be turned on according to the enable signal to respectively transmit the second signal and the third signal to a corresponding one of the plurality of first switches and a corresponding one of the plurality of second switches.

6. The comparator of claim 2, wherein the digital-to-analog converter circuit comprises:
a voltage divider circuit configured to generate the plurality of reference voltages; and
a selection circuit configured to select the first reference voltage and the second reference voltage from the plurality of reference voltages according to the first signal.

7. An analog-to-digital converter, comprising:
a plurality of comparator circuits configured to generate a plurality of decision signals according to an input signal;
an offset calculation circuit configured to calculate an offset of the plurality of comparator circuits according to the plurality of decision signals to generate a plurality sets of control signals;
a hybrid offset voltage generation circuit configured to select a first reference voltage and a second reference voltage from a plurality of reference voltages according to the plurality sets of control signals and utilize the first reference voltage and the second reference voltage to perform a charge transfer operation to generate a plurality sets of calibration voltages; and
a plurality of offset cancellation circuits configured to cancel the offset according to the plurality sets of calibration voltages.

8. The analog-to-digital converter of claim 7, wherein the hybrid offset voltage generation circuit comprises:
a digital-to-analog converter circuit configured to generate the plurality of reference voltages and to select the first reference voltage and the second reference voltage from the plurality of reference voltages according to a first signal of the plurality sets of control signals; and
a plurality sets of switching capacitor circuits configured to perform the charge transfer operation according to the first reference voltage, the second reference voltage, and a plurality of corresponding signals in the plurality sets of control signals to generate the plurality sets of calibration voltages.

9. The analog-to-digital converter of claim 8, wherein a set number of the plurality sets of switching capacitor circuits is the same as a number of the plurality of comparator circuits.

10. An offset cancellation method, comprising:
generating, by a comparator circuit, a decision signal according to an input signal;
calculating an offset of the comparator circuit according to the decision signal to generate a plurality of control signals;
selecting a first reference voltage and a second reference voltage from a plurality of reference voltages according to the plurality of control signals, in order to utilize the first reference voltage and the second reference voltage to perform a charge transfer operation to generate a plurality of calibration voltages; and
cancelling the offset of the comparator circuit according to the plurality of calibration voltages.

11. The offset cancellation method of claim 10, wherein selecting the first reference voltage and the second reference voltage from the plurality of reference voltages according to the plurality of control signals and utilizing the first reference voltage and the second reference voltage to perform the charge transfer operation to generate the plurality of calibration voltages comprises:
generating the plurality of reference voltages and selecting the first reference voltage and the second reference voltage from the plurality of reference voltages according to a first signal of the plurality of control signals; and
performing, by a plurality of switching capacitor circuits, the charge transfer operation according to a second signal and a third signal of the plurality of control signals, the first reference voltage, and the second reference voltage, to generate the plurality of calibration voltages.

12. The offset cancellation method of claim 11, wherein the plurality of switching capacitor circuits comprise a first switching capacitor circuit and a second switching capacitor circuit, and performing, by the plurality of switching capacitor circuits, the charge transfer operation according to the second signal and the third signal of the plurality of control signals, the first reference voltage, and the second reference voltage, to generate the plurality of calibration voltages comprises:
performing, by the first switching capacitor circuit, the charge transfer operation according to the first reference voltage, the second signal, and one of a ground voltage and the second reference voltage, to generate a first calibration voltage of the plurality of calibration voltages; and
performing, by the second switching capacitor circuit, the charge transfer operation according to the second reference voltage, the third signal, and one of the ground voltage and the first reference voltage, to generate a second calibration voltage of the plurality of calibration voltages.

13. The offset cancellation method of claim 12, wherein performing, by the first switching capacitor circuit, the charge transfer operation according to the first reference voltage, the second signal, and the one of the ground voltage and the second reference voltage, to generate the first calibration voltage comprises:
generating, by an inverter in the first switching capacitor circuit, an inverted signal according to the second signal, wherein the inverter is powered by the first reference voltage and the one of the ground voltage and the second reference voltage;
turning on a plurality of switches in the first switching capacitor circuit according to a plurality of clock signals to transmit the inverted signal to a plurality of capacitors in the first switching capacitor circuit; and
performing, by the plurality of capacitors, the charge transfer operation in response to the inverted signal to generate the first calibration voltage.

14. The offset cancellation method according to claim 12, wherein the first switching capacitor circuit comprises a plurality of first switches, a plurality of second switches, a plurality of third switches, a plurality of first capacitors, and a plurality of second capacitors, and performing, by the first switching capacitor circuit, the charge transfer operation according to the first reference voltage, the second signal, and the one of the ground voltage and the second reference voltage, to generate the first calibration voltage comprises:
selectively turning on the plurality of first switches according to the second signal and an enable signal, wherein the plurality of first switches are coupled in series and between a first node and an output node, and the first node is configured to receive the first reference voltage;
selectively turning on the plurality of second switches according to the third signal and the enable signal, wherein the plurality of second switches are coupled in series and between the output node and a second node, and the second node is configured to receive one of the ground voltage and the second reference voltage;
performing, by the plurality of first capacitors and the plurality of second capacitors, the charge transfer operation through the plurality of first switches and the plurality of second switches, to output the first calibration voltage via the output node,
wherein the plurality of first capacitors are coupled to the plurality of first switches, and the plurality of second capacitors are coupled to the plurality of second switches; and
turning on the plurality of third switches according to the enable signal to respectively transmit the second signal and the third signal to a corresponding one of the plurality of first switches and a corresponding one of the plurality of second switches.

15. The offset cancellation method according to claim 11, wherein generating the plurality of reference voltages and selecting the first reference voltage and the second reference voltage from the plurality of reference voltages according to the first signal comprises:
generating, by a voltage divider circuit, the plurality of reference voltages; and
selecting, by a selection circuit, the first reference voltage and the second reference voltage from the plurality of reference voltages according to the first signal.
